(19) United States
(12) Patent Application Publication
(10) Pub. No.: US 2015/0214307 A1
(43) Pub. Date: Jul. 30, 2015

(54) METHOD FOR MANUFACTURING SEMICONDUCTOR DEVICE

(71) Applicant: Mitsubishi Electric Corporation, Tokyo (JP)

(72) Inventor: Harunaka Yamaguchi, Tokyo (JP)

(21) Appl. No.: 14/507,884

(22) Filed: Oct. 7, 2014

(30) Foreign Application Priority Data
Jan. 27, 2014 (JP) 2014-012509

(51) Int. Cl. H01L 29/201; H01L 31/107; H01L 31/0304; H01L 21/306; H01L 29/207; H01L 29/10; H01L 29/66; H01L 21/02; H01L 31/18; H01S 5/343

(52) U.S. Cl. CPC H01L 29/201; H01L 31/1844; H01L 31/1075; H01L 31/03042; H01L 31/03046; H01S 5/34313; H01S 5/34353; H01L 29/207; H01L 29/1033; H01L 29/1004; H01L 29/6631; H01L 29/66522; H01L 21/02546; H01L 21/30604

(57) ABSTRACT

A method for manufacturing a semiconductor device includes: forming a buffer layer on a substrate; and sequentially forming an undoped multiplication layer, an electric field alleviating layer, a light absorption layer, and a window layer on the buffer layer, in that order, for forming an avalanche photodiode. Carbon is incorporated into the electric field alleviating layer as a p-type dopant, and a dopant impurity producing n-type conductivity and carbon are incorporated into the buffer layer.

### BACKGROUND OF THE INVENTION

1. Field of the Invention

The present invention relates to a method for manufacturing a semiconductor device which can improve device characteristics and reliability.

2. Background Art

With the trend toward higher performance, optical devices or electronic devices are required to include locally higher concentration p-type semiconductor layers. For this reason, carbon, which is a low-diffusion dopant, is often used (e.g., see IEEE PHOTONICS TECHNOLOGY LETTERS, VOL. 20, NO. 6, MAR. 15, 2008 and IEEE PHOTONICS TECHNOLOGY LETTERS, VOL. 18, NO. 1, JAN. 1, 2006). Electron multiplication type avalanche photodiodes using AlInAs for a multiplication layer are becoming a focus of attention to realize low noise, high sensitivity, and high-speed response in optical devices. A high carbon-doped p-type AlInAs layer is used for an electric field alleviating layer to control avalanche mode. Moreover, in electronic devices, carbon is used as a p-type base layer dopant to improve efficiency of heterojunction bipolar transistors having signal amplification action for mobile phones.

High carbon-doped p-type layers are obtained under singular growth conditions, such as low temperature, low Group V source material flow rate, and are further more easily obtained in a crystalline material containing Al as one of its constituents. Al is an extremely active material, impurities other than carbon (oxygen in particular) are easily incorporated into a crystalline based on growth conditions. Unintended impurities are incorporated into the growing crystalline material as source materials are supplied to a crystalline growth furnace, adversely affecting device characteristics and reliability. In a laminated structure, this phenomenon is conspicuously observed in an Al-containing crystalline layer in an initial stage of growth of the carbon-doped first layer, but such a phenomenon is not observed after the initial portion of growth or in the layer grown above the carbon-doped layer.

In an electron multiplication type avalanche photodiode using carbon-doped AlInAs as an electric field alleviating layer, an impurity, such as oxygen, incorporated in the electric field alleviating layer behaves like a defect. Since a light absorption layer, which is an active layer, is grown after the growth of the electric field alleviating layer, the multiplication characteristic or reliability is deteriorated. On the other hand, in a heterojunction bipolar transistor using a carbon-doped base layer, an impurity contained in the base layer becomes a defect, which is a factor in inhibiting charge carrier flow and adversely affects reliability.

What is common to both cases is that only one carbon-doped layer exists in the device structure and the carbon-doped layer exists in the vicinity of the active layer. This causes not only a growth condition under which it is difficult to obtain satisfactory crystallinity, but also results in unintended incorporation of the impurity into the carbon-doped layer near the active layer, adversely affecting device characteristics and reliability.

### SUMMARY OF THE INVENTION

In view of the above-described problems, an object of the present invention is to provide a method for manufacturing a semiconductor device which produces improved device characteristics and reliability.

According to the present invention, a method for manufacturing a semiconductor device includes: forming a buffer layer on a substrate; and sequentially forming an undoped multiplication layer, an electric field alleviating layer, a light absorption layer, and a window layer on the buffer layer, in that order, for forming an avalanche photodiode. Carbon is incorporated into the electric field alleviating layer as a p-type dopant, and a dopant impurity producing n-type conductivity and carbon are incorporated into the buffer layer.

The present invention makes it possible to inhibit unintended incorporation of an impurity into the carbon-doped electric field alleviating layer, and thereby improves device characteristics and reliability.

Other and further objects, features and advantages of the invention will appear more fully from the following description.

### BRIEF DESCRIPTION OF THE DRAWINGS

FIG. 1 is a cross-sectional view illustrating a semiconductor device according to a first embodiment of the present invention.

FIG. 2 is a diagram illustrating SIMS analysis of impurity concentration in a laminated structure of carbon-doped AlInAs and InP grown on an InP substrate.

FIG. 3 is a diagram illustrating a change of carrier concentration when carbon and Si are simultaneously doped into Si-doped AlInAs.

FIG. 4 is a cross-sectional view illustrating a semiconductor device according to a fourth embodiment of the present invention.

FIG. 5 is a cross-sectional view illustrating a semiconductor device according to a fifth embodiment of the present invention.

FIG. 6 is a cross-sectional view illustrating a semiconductor device according to a sixth embodiment of the present invention.

### DETAILED DESCRIPTION OF THE PREFERRED EMBODIMENTS

A method for manufacturing a semiconductor device according to embodiments of the present invention will be described with reference to the drawings. The same components will be denoted by the same symbols, and the repeated description thereof may be omitted.

### First Embodiment

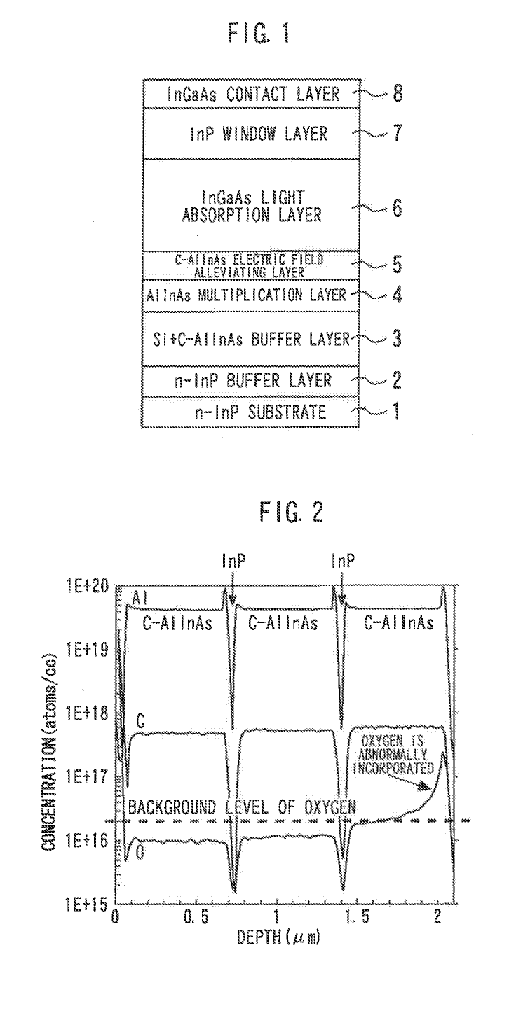

FIG. 1 is a cross-sectional view illustrating a semiconductor device according to a first embodiment of the present invention. This semiconductor device is an avalanche photodiode in which an n-type InP buffer layer 2 having a carrier concentration of 3 to 5×10¹⁸ cm⁻³ and a thickness of 0.1 to 1 μm, an n-type AlInAs buffer layer 3 having a carrier concentration of 3 to 5×10¹⁸ cm⁻³ and a thickness of 0.1 to 0.5 μm, an undoped AlInAs avalanche multiplication layer 4 having a thickness of 0.1 to 0.5 μm, a p-type AlInAs electric field alleviating layer 5 having a carrier concentration of 0.5 to 1×10¹⁸ cm⁻³ and a thickness of 0.05 to 0.15 μm, an n⁻-type InGaAs light absorption layer 6 having a carrier concentration of 1 to 5×10¹⁵ cm⁻³ and a thickness of 1 to 2 μm, an n⁻-type InP window layer 7 having a carrier concentration of 0.01 to 0.1×10¹⁵ cm⁻³ and a thickness of 0.5 to 1 μm, and a p-type InGaAs contact layer 8 having a carrier concentration of 1 to 5×10¹⁸ cm⁻³ and a thickness of 0.1 to 0.5 μm, are laminated, in that order, on an n-type InP substrate 1. A p-type region (not shown) is located in the n⁻-type InP window layer 7.

Next, a method for manufacturing the semiconductor device according to the present embodiment will be described. The growth method for each semiconductor layer is, for example, metal organic vapor phase epitaxy (MOVPE) or molecular beam epitaxy (MBE).

First, the n-type InP buffer layer 2, the n-type AlInAs buffer layer 3, and the undoped AlInAs avalanche multiplication layer 4 are grown on the n-type InP substrate 1 in the crystalline growth furnace using MOVPE and at a growth temperature of 630° C. Si, which is a dopant impurity producing n-type conductivity, and carbon are incorporated into the n-type AlInAs buffer layer 3 produce a carrier concentration of 3 to 5×10¹⁸ cm⁻³.

Next, the growth temperature is lowered to close to 580° C. and the p-type AlInAs electric field alleviating layer 5 is grown in the crystalline growth furnace. Carbon is incorporated into the p-type AlInAs electric field alleviating layer 5 as a p-type dopant.

Next, the growth temperature is increased to 630° C. to grow the n⁻-type InGaAs light absorption layer 6, the n⁻-type InP window layer 7, and the p-type InGaAs contact layer 8, in that order, in the crystalline growth furnace.

FIG. 2 is a diagram illustrating SIMS analysis of impurity concentration in a laminated structure of carbon-doped AlInAs and InP grown on an InP substrate. This analysis shows that oxygen is abnormally incorporated at the initial stage of growth of carbon-doped AlInAs in the first layer. This phenomenon is assumed to take place due to reaction of a halogen, which is a constituent element of a carbon source material, in the crystalline growth furnace, and bonding of Al with oxygen remaining in the crystal growth furnace. The Al comes from an organic metal material thermally cracked in the crystalline growth furnace and is extremely active. Further, such incorporation of oxygen is not observed in carbon-doped AlInAs in the second layer and the third layer. The present invention takes advantage of this phenomenon.

Since gettering takes place during the growth of the n-type AlInAs buffer layer 3 due to influence of the carbon dopant source material (CBr₄ or the like) or active Al material, oxygen remaining in the crystalline growth furnace can be trapped in the n-type AlInAs buffer layer 3. Therefore, it is possible to prevent incorporation of oxygen into the carbon-doped p-type AlInAs electric field alleviating layer 5 that is located above the n-type AlInAs buffer layer 3. The n-type AlInAs buffer layer 3 is located below the undoped AlInAs avalanche multiplication layer 4 and the p-type AlInAs electric field alleviating layer 5 and is near the substrate. The n-type AlInAs buffer layer 3 is, therefore, remote from the n⁻-type InGaAs light absorption layer 6 in which charge carriers are generated during operation of the avalanche photodiode, making it possible to reduce the influence of crystalline defects produced by oxygen.

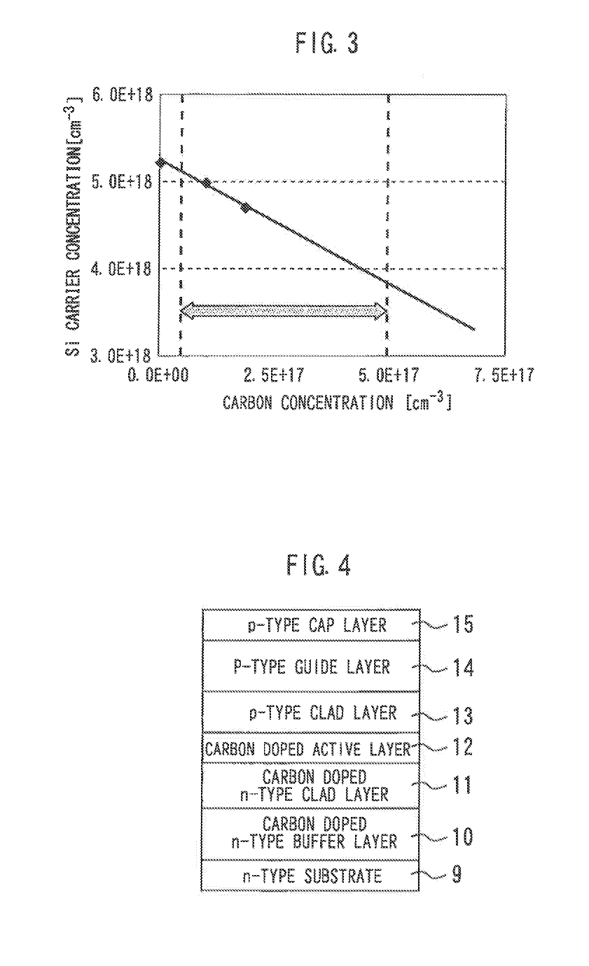

FIG. 3 is a diagram illustrating a change of carrier concentration when carbon and silicon (Si) are simultaneously incorporated into Si-doped AlInAs. While Si-doped AlInAs exhibits n-type conductivity, carbon-doped AlInAs exhibits p-type conductivity. For this reason, when both are simultaneously incorporated, increasing the amount of carbon will gradually decrease carrier concentration as the n-type conductivity decreases. The n-type carrier concentration of the n-type AlInAs buffer layer 3 is preferably 3×10¹⁸ cm⁻³ or above so as to have no influence on depletion of the buffer layer during a device operation. It is necessary to generate gettering action to a certain degree and prevent the remaining oxygen from being incorporated into the carbon-doped layer in the second layer. To satisfy both conditions, the ratio of carbon to n-type conductivity impurity Si in the n-type AlInAs buffer layer 3 is preferably in a range from 1/10 to 1/100.

As described above, in the present embodiment, oxygen is taken into the n-type AlInAs buffer layer 3 located remotely from the n⁻-type InGaAs light absorption layer 6. This can inhibit unintended incorporation of oxygen into the carbon-doped p-type AlInAs electric field alleviating layer 5 near the n⁻-type InGaAs light absorption layer 6, and can thereby improve device characteristics such as multiplication characteristic and reliability.

Note that the p-type layer can be formed not only by incorporating a dopant impurity but also by Zn diffusion. Without being limited to the n-type InP substrate, an equivalent structure may be grown on a semi-insulating substrate. Furthermore, when the laminated structure is placed upside down and grown starting with the p-type layer, the same effect can be obtained if carbon and Si are simultaneously incorporated during the growth of the first p-type contact layer. In this case, carbon is incorporated into the contact layer simultaneously with the other p-type dopant, but since carbon is originally a p-type dopant, there is no problem. Moreover, since p-type carrier concentration can be increased, contact resistance can also be reduced.

### Second Embodiment

The first embodiment prompts gettering action by doping the n-type AlInAs buffer layer 3 with carbon using a carbon halide as a source of carbon. However, since carbon-doped AlInAs inhibits n-type conductivity that is produced by Si that is simultaneously incorporated to produce p-type conductivity, it is necessary to control the amount of carbon supplied.

In the present embodiment, the n-type AlInAs buffer layer 3 is not doped. Instead, the n-type InP buffer layer 2 is doped with carbon together with Si. InP doped with carbon exhibits n-type conductivity. Therefore, since there is no carbon that acts as an acceptor in the buffer layer, concentration control of dopant impurities in the buffer layer becomes easier. Moreover, it is possible to create a situation in which a dopant impurity in the crystalline growth furnace is more easily incorporated into InP. Since an impurity such as oxygen or carbon is less likely to be taken into InP than into AlInAs, it is possible to grow an n-type InP buffer layer 2 of good crystallinity.

In addition, as in the case of the first embodiment, it is possible to inhibit unintended incorporation of oxygen into the p-type AlInAs electric field alleviating layer 5 doped with carbon in the vicinity of the n⁻-type InGaAs light absorption layer 6, and thereby improve device characteristics, such as multiplication characteristic and reliability.

### Third Embodiment

The present embodiment employs CBr₄ as a carbon source material including a halogen as a constituent element. The CBr₄ is introduced into the crystalline growth furnace before forming the n-type InP buffer layer 2 and etches the surface of the n-type InP substrate 1 and cleans the surface for 1 to 10 minutes. After that, in the present embodiment crystalline growth is carried out as in the first and second embodiments.

The materials introduced before crystalline growth may be not only CBr₄ but also a carbon source material having halogen as its constituent element such as CCl₃Br (carbon trichloride bromide) and TBCl (tertiary butyl chloride).

Moreover, a material that produces a reduction action when thermally cracked, such as an Al-containing organic source material (trimethyl aluminum or the like) may be introduced into the crystalline growth furnace to reduce the surface of the n-type InP substrate 1.

Thus, by introducing a carbon source material having a halogen as a constituent element or an Al-containing organic source material before crystalline growth, it is thereby possible to getter oxygen remaining in the crystalline growth furnace, and thereby prevent the oxygen from being taken into the crystalline layer that is grown. Furthermore, it is possible to perform the reduction reaction on the substrate surface, remove impurities deposited on the substrate surface, prevent characteristic deterioration caused by the impurities, and thereby grow a buffer layer of high quality.

The processing before crystalline growth according to the present embodiment is applicable not only to a method for manufacturing a light-receiving device but also to a method for manufacturing a light-emitting device or electronic device which will be described later, and can achieve similar effects.

### Fourth Embodiment

FIG. 4 is a cross-sectional view illustrating a semiconductor device according to a fourth embodiment of the present invention. This semiconductor device is a modulation-doped semiconductor laser in which an n-type InP buffer layer 10, an n-type InP cladding layer 11, an AlGaInAs quantum well active layer 12, a barrier layer which is modulation-doped with carbon, a p-type InP cladding layer 13, a p-type guide layer 14, and a p-type cap layer 15 are laminated, in that order, on an n-type InP substrate 9.

Next, a method for manufacturing the semiconductor device according to the present embodiment will be described. Using MOVPE, the n-type InP buffer layer 10 is grown on the n-type InP substrate 9 in the crystalline growth furnace. The n-type InP cladding layer 11, the AlGaInAs quantum well active layer 12, the p-type InP cladding layer 13, the p-type guide layer 14, and the p-type cap layer 15 are grown, in that order, on the n-type InP buffer layer 10 in the crystalline growth furnace. At least one of the n-type InP buffer layer 10 and the n-type InP cladding layer 11 is doped with carbon together with a dopant impurity producing n-type conductivity.

Doping with carbon using a carbon source material including a halogen as a constituent, as well as doping with a donor, such as Si or S, is conducted to produce the n-type InP cladding layer 11, which has a carrier concentration of 1×10¹⁸ cm⁻³. The p-type InP cladding layer 13 is controlled, using Zn or the like, to have a carrier concentration of 1×10¹⁸ cm⁻³.

As described above, the present embodiment incorporates at least one of the n-type InP buffer layer 10 and the n-type InP cladding layer 11 doped with carbon as well as a dopant impurity producing n-type conductivity. As a result, these layers, located remotely from the AlGaInAs quantum well active layer 12, incorporate an impurity in the crystalline growth furnace. This process prevents unintended incorporation of oxygen into the carbon-doped AlGaInAs quantum well active layer 12, and can thereby improve device characteristics such as light-emission intensity, efficiency, and reliability.

Even when GaAs is used instead of InP as the substrate, similar growth is also possible using AlGaInP as the material of the active layer. In addition, even when the conductivity of the substrate is p-type, similar growth is also possible by adopting an n-type layer above the active layer. The conductivity of the semiconductor substrate is not particularly questioned.

### Fifth Embodiment

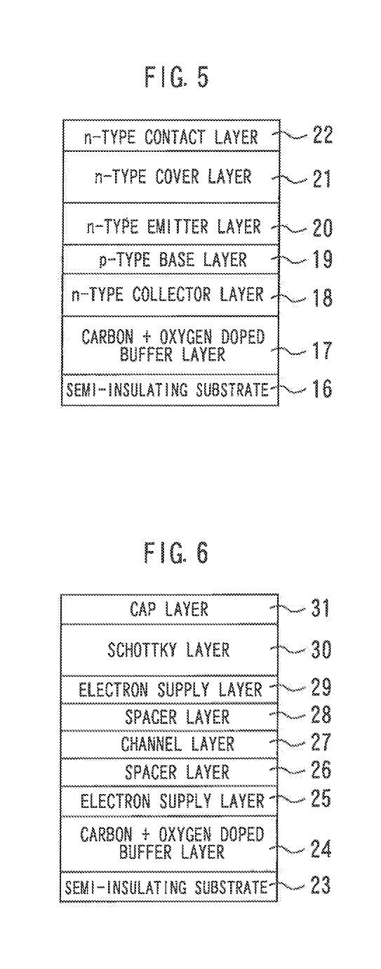

FIG. 5 is a cross-sectional view illustrating a semiconductor device according to a fifth embodiment of the present invention. This semiconductor device is a bipolar transistor in which an AlGaAs buffer layer 17 doped with oxygen and carbon, an n-type GaAs collector layer 18, a p-type GaAs base layer 19, an n-type InGaP emitter layer 20, an n-type GaAs cover layer 21, and an n-type InGaAs contact layer 22 are laminated, in that order, on a semi-insulating GaAs substrate 16.

Next, a method for manufacturing the semiconductor device according to the present embodiment will be described. Using MOVPE, the AlGaAs buffer layer 17 is grown on the semi-insulating GaAs substrate 16 in the crystalline growth furnace. The n-type GaAs collector layer 18, the p-type GaAs base layer 19, the n-type InGaP emitter layer 20, the n-type GaAs cover layer 21, and the n-type InGaAs contact layer 22 are grown, in that order, on the AlGaAs buffer layer 17 in the crystalline growth furnace.

Here, the amount of the Group V element supplied when the AlGaAs buffer layer 17 is grown is adjusted. Oxygen in the crystalline growth furnace is taken into the AlGaAs buffer layer 17 with a concentration equal to or higher than that of carbon. The p-type GaAs base layer 19 is doped with carbon as a p-type dopant using an organic halide compound as a carbon source material to produce a carrier concentration of 2 to 3×10¹⁸ cm⁻³. The n-type InGaP emitter layer 20 is grown to have a carrier concentration of 0.1 to 1×10¹⁸ cm⁻³, and the n-type GaAs cover layer 21 and the n-type InGaAs contact layer 22 are grown to have a carrier concentration of on the order of 5×10¹⁸cm⁻³.

As described above, in the present embodiment, oxygen in the crystalline growth furnace is taken into the AlGaAs buffer layer 17 with a concentration equal to or higher than that of carbon. It is thereby possible to inhibit unintended incorporation of oxygen into the carbon-doped p-type GaAs base layer 19. On the other hand, the AlGaAs buffer layer 17 doped with a high concentration of oxygen has high resistivity so that leakage current during device operation decreases. For this reason, it is possible to improve device characteristics, such as amplification efficiency and reliability.

Even when InP instead of GaAs is used as the material of the substrate or the like, similar growth can be achieved using AlInAs or InGaAs as the materials of the base layer and the emitter layer. Furthermore, the carbon-doped base layer can grow not only using a carbon source material including a halogen as a constituent element, but also by doping with carbon supplied from a methyl group compound including a Group III element.

### Sixth Embodiment

FIG. 6 is a cross-sectional view illustrating a semiconductor device according to a sixth embodiment of the present invention. This semiconductor device is a field-effect type transistor in which an AlGaAs buffer layer 24 doped with oxygen and carbon, an n-type AlGaAs electron supply layer 25, an undoped AlGaAs spacer layer 26, an undoped InGaAs channel layer 27, an undoped AlGaAs spacer layer 28, an n-type AlGaAs electron supply layer 29, an n-type AlGaAs Schottky layer 30, and an n-type GaAs cap layer 31 are laminated, in that order, on a semi-insulating GaAs substrate 23.

Next, a method for manufacturing the semiconductor device according to the present embodiment will be described. Using MOVPE, the AlGaAs buffer layer 24 is grown on the semi-insulating GaAs substrate 23 in the crystalline growth furnace. The n-type AlGaAs electron supply layer 25, the undoped AlGaAs spacer layer 26, the undoped InGaAs channel layer 27, the undoped AlGaAs spacer layer 28, the n-type AlGaAs electron supply layer 29, the n-type AlGaAs Schottky layer 30, and the n-type GaAs cap layer 31 are grown, in that order, on the AlGaAs buffer layer 24 in the crystalline growth furnace.

Here, the amount of a Group V element supplied when the AlGaAs buffer layer 24 is grown is adjusted. Oxygen in the crystalline growth furnace is taken into the AlGaAs buffer layer 24 with a concentration equal to or higher than that of carbon. The n-type AlGaAs electron supply layers 25 and 29 are grown to have a carrier concentration of 1 to 2×10¹⁸ cm⁻³, the n-type AlGaAs Schottky layer 30 is undoped or made to have a carrier concentration of 1×10¹⁷ cm⁻³ or less, and the n-type GaAs cap layer 31 is made to have a carrier concentration of on the order of 5×10¹⁸ cm⁻³.

As described above, when the AlGaAs buffer layer 24 is grown, the present embodiment adjusts the amount of the Group V element supplied, and causes oxygen in the crystalline growth furnace to be taken into the AlGaAs buffer layer 24 with a concentration equal to or higher than that of carbon. It is thereby possible to inhibit unintended incorporation of oxygen into the channel layer and the electron supply layer. Moreover, since the AlGaAs buffer layer 24 doped with high concentration oxygen exhibits high resistivity, leakage current during device operation decreases. For this reason, it is possible to improve device characteristics, such as switching speed, amplification efficiency, and reliability.

Note that the InGaAs layer on GaAs has an extremely small critical film thickness within which the layer is grows, due to a lattice mismatch. The layer thickness is preferably set to be equal to or less than 20 nm. In addition to GaAs, similar growth is also available using InP or using InP or AlInAs or the like for the electron supply layer.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2014-012509, filed on Jan. 27, 2014 including specification, claims, and summary, on which the Convention priority of the present application is based, is incorporated herein by reference in its entirety.

What is claimed is:

1. A method for manufacturing a semiconductor device comprising:
forming a buffer layer on a substrate; and
sequentially forming an undoped multiplication layer, an electric field alleviating layer, a light absorption layer, and a window layer on the buffer layer, in that order, for forming an avalanche photodiode, including
incorporating carbon into the electric field alleviating layer as an a p-type dopant, and
incorporating a dopant impurity producing n-type conductivity and carbon into the buffer layer.

2. The method according to claim 1, wherein the buffer layer is a crystalline material containing Al.

3. The method according to claim 1, including incorporating the carbon in the buffer layer in a concentration ratio to the dopant impurity producing n-type conductivity in the buffer layer in a range from 1/10 to 1/100.

4. The method according to claim 1, further comprising, before forming the buffer layer, introducing a carbon source material including a halogen and etching a surface of the substrate.

5. The method according to claim 1, further comprising, before forming the buffer layer, introducing an Al-containing organic source material and reducing a surface of the substrate.

6. The method according to claim 1, including incorporating silicon as the dopant impurity producing n-type conductivity is silicon.

7. A method for manufacturing a semiconductor device comprising:
forming a buffer layer on a substrate; and
sequentially forming a first conductivity type cladding layer, an active layer, and a second conductivity type cladding layer on the buffer layer, in that order, for forming a semiconductor laser, including
incorporating carbon into the active layer, and
incorporating a dopant impurity producing n-type conductivity and carbon into at least one of the buffer layer and the first conductivity type cladding layer.

8. The method according to claim 7, further comprising, before forming the buffer layer, introducing a carbon source material including a halogen and etching a surface of the substrate.

9. The method according to claim 7, further comprising, before forming the buffer layer, introducing an Al-containing organic source material and reducing a surface of the substrate.

10. The method according to claim 7, wherein the dopant impurity producing n-type conductivity is silicon.

11. A method for manufacturing a semiconductor device comprising:
forming a buffer layer on a substrate; and
sequentially forming a collector layer, a base layer, and an emitter layer on the buffer layer, in that order, for forming a bipolar transistor, including
incorporating carbon into the base layer as a p-type dopant, and
incorporating carbon into the buffer layer at a carbon concentration, wherein oxygen is taken into the buffer layer with a concentration of at least equal to the carbon concentration in the buffer layer.

12. The method according to claim 11, further comprising, before forming the buffer layer, introducing a carbon source material including a halogen and etching a surface of the substrate.

13. The method according to claim 11, further comprising, before forming the buffer layer, introducing an Al-containing organic source material and reducing a surface of the substrate.

14. A method for manufacturing a semiconductor device comprising:
forming a buffer layer on a substrate; and
sequentially forming an electron supply layer and a channel layer on the buffer layer for forming a field-effect type transistor, wherein the channel layer is InGaAs, and including incorporating carbon into the buffer layer in a carbon concentration, and wherein oxygen is taken into the buffer layer with a concentration at least equal to the carbon concentration in the carbon.

15. The method according to claim 14, further comprising, before forming the buffer layer, introducing a carbon source material including a halogen and etching a surface of the substrate.

16. The method according to claim 14, further comprising, before forming the buffer layer, introducing an Al-containing organic source material and reducing a surface of the substrate.
